(19) United States
(12) Patent Application Publication
(10) Pub. No.: US 2025/0379089 A1
(43) Pub. Date: Dec. 11, 2025

(54) ELECTROSTATIC CHUCK AND SUBSTRATE FIXING DEVICE

(71) Applicant: SHINKO ELECTRIC INDUSTRIES CO., LTD., Nagano-shi (JP)

(72) Inventors: Masahiro Sunohara, Nagano-shi (JP); Ken Sato, Nagano-shi (JP); Hiroyuki Kobayashi, Nagano-shi (JP); Hiroshi Ishii, Nagano-shi (JP)

(21) Appl. No.: 19/230,254

(22) Filed: Jun. 6, 2025

(30) Foreign Application Priority Data
Jun. 11, 2024 (JP) 2024-094186

(51) Int. Cl. H01L 21/683

(52) U.S. Cl. CPC H01L 21/6833

(57) ABSTRACT

An electrostatic chuck includes a ceramic plate, an adsorption electrode, a ground electrode, and a wiring. The adsorption electrode is built-in below one surface of the ceramic plate. The ground electrode is disposed between another surface of the ceramic plate and the adsorption electrode in the ceramic plate and connectable to a ground potential. The wiring is connected to the ground electrode in the ceramic plate and extending through the adsorption electrode to the one surface of the ceramic plate. The wiring includes a connection pad disposed at a same height position as the adsorption electrode, a first via connecting the connection pad and the ground electrode or another connection pad disposed closer to the ground electrode than the connection pad, and a second via connecting the connection pad and the one surface of the ceramic plate.

### TECHNICAL FIELD

The present invention relates to an electrostatic chuck and a substrate fixing device.

### BACKGROUND ART

In general, an electrostatic chuck (ESC) configured using a ceramic plate having a built-in adsorption electrode is provided in a substrate fixing device that adsorbs and holds a substrate such as a wafer when manufacturing, for example, a semiconductor component. The substrate fixing device has a structure in which an electrostatic chuck is fixed to a base plate, and adsorbs the substrate to the electrostatic chuck using an electrostatic force by applying a voltage to the adsorption electrode built in the ceramic plate. By adsorbing and holding the substrate on the electrostatic chuck, processes such as microfabrication and etching on the substrate are efficiently performed.

The ceramic plate constituting the electrostatic chuck is formed, for example, by laminating and firing green sheets made of aluminum oxide and an auxiliary agent. The adsorption electrode is built in near an adsorption surface of the ceramic plate that adsorbs the substrate. When the substrate is adsorbed by the electrostatic chuck, a voltage is applied to the adsorption electrode, and when the substrate is detached from the electrostatic chuck, the application of the voltage to the adsorption electrode is stopped.

Even when the application of the voltage to the adsorption electrode is stopped, electric charges may remain on the adsorption surface of the ceramic plate. The electric charges remaining on the adsorption surface generates an adsorption force corresponding to the electric charges between the adsorption surface and the substrate, which may hinder the detachment of the substrate from the adsorption surface. For this reason, a wiring and a ground electrode for allowing electric charges to escape from the adsorption surface to the ground potential are formed inside the ceramic plate.

Specifically, the ground electrode connectable to a ground potential is formed on a green sheet laminated between a surface of the ceramic plate on an opposite side to the adsorption surface and the adsorption electrode, and a conductive connection pad is formed on a surface of each green sheet adjacent to the green sheet. The ground electrode and the connection pad, the connection pad and the connection pad formed on the adjacent green sheets, and the connection pad and the adsorption surface are connected to each other by vias penetrating the green sheets. As a result, in a state where the plurality of green sheets are laminated, a wiring that passes through the adsorption electrode and connects the ground electrode and the adsorption surface of the ceramic plate is formed by the connection pad and the via formed in each green sheet.

### SUMMARY OF INVENTION

However, in the electrostatic chuck in which the wiring passing through the adsorption electrode is formed, there is a problem that connection reliability of the wiring is lowered due to a positional deviation of the via generated in a passing portion of the wiring in the adsorption electrode.

Specifically, in the passing portion of the wiring in the adsorption electrode, a via penetrating the green sheet on which the adsorption electrode is formed and a via penetrating another green sheet on which the adsorption electrode is not formed are connected to form a wiring portion. The green sheet on which the adsorption electrode is formed is limited in thermal shrinkage as compared with the other green sheets on which the adsorption electrode is not formed. As described above, since the green sheet on which the adsorption electrode is formed and the other green sheet are laminated and fired, after the firing heated at a high temperature, the positional deviation of the via occurs at the passing portion of the wiring in the adsorption electrode due to a difference in an amount of thermal shrinkage between the green sheets. As a result, a contact area of the via becomes smaller at the passing portion of the wiring in the adsorption electrode, and the connection between the vias is hindered, which may cause resistance failure or disconnection in the wiring portion.

The present disclosure has been made in view of the above, and an object of the present disclosure is to provide an electrostatic chuck and a substrate fixing device that can improve connection reliability of a wiring passing through an adsorption electrode.

According to one aspect of the present disclosure, an electrostatic chuck includes a ceramic plate, an adsorption electrode, a ground electrode, and a wiring. The adsorption electrode is built-in below one surface of the ceramic plate. The ground electrode is disposed between another surface of the ceramic plate and the adsorption electrode in the ceramic plate and is connectable to a ground potential. The wiring is connected to the ground electrode in the ceramic plate, and extends through the adsorption electrode to the one surface of the ceramic plate. The wiring includes a connection pad disposed at a same height position as the adsorption electrode, a first via connecting the connection pad and the ground electrode or another connection pad disposed closer to the ground electrode than the connection pad, and a second via connecting the connection pad and the one surface of the ceramic plate.

According to the one aspect of the electrostatic chuck disclosed in the present application, it is possible to improve the connection reliability of the wiring passing through the adsorption electrode.

### BRIEF DESCRIPTION OF DRAWINGS

FIG. 1 is a perspective view showing a configuration of a substrate fixing device according to a first embodiment.

FIG. 2 is a schematic view showing a cross section of the substrate fixing device according to the first embodiment.

FIG. 3 is a flowchart showing a method for manufacturing the substrate fixing device according to the first embodiment.

FIG. 4 is a schematic view showing a cross section of a substrate fixing device according to a modification of the first embodiment.

FIG. 5 is a schematic view showing a cross section of a substrate fixing device according to a second embodiment.

FIG. 6 is a schematic view showing a cross section of a substrate fixing device according to a third embodiment.

FIG. 7 is a schematic view showing a cross section of a substrate fixing device according to a fourth embodiment.

FIG. 8 is a schematic view showing a cross section of a substrate fixing device according to a fifth embodiment.

FIG. 9 is a schematic view showing a cross section of a substrate fixing device according to a sixth embodiment.

FIG. 10 is a schematic view showing a cross section of a substrate fixing device according to a seventh embodiment.

### DESCRIPTION OF EMBODIMENTS

Hereinafter, embodiments of an electrostatic chuck and a substrate fixing device disclosed in the present application will be described in detail with reference to the drawings. The disclosed technology is not limited by the embodiments. The embodiments can be combined as appropriate. In the following embodiments, the same parts are denoted by the same reference numerals, and redundant description will be omitted.

### First Embodiment

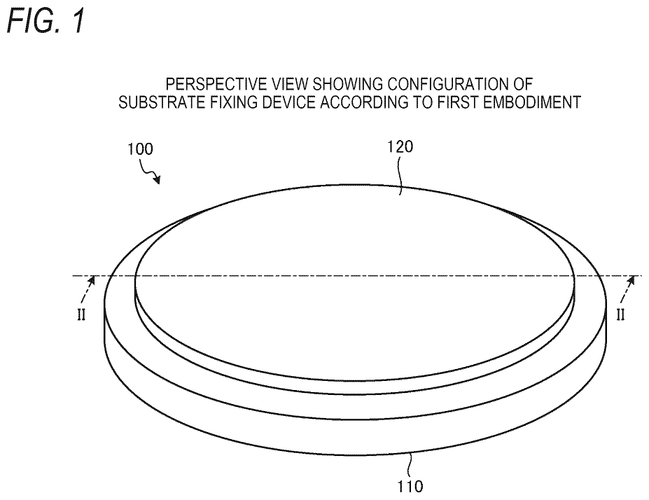

FIG. 1 is a perspective view showing a configuration of a substrate fixing device 100 according to a first embodiment. The substrate fixing device 100 shown in FIG. 1 has a structure in which an electrostatic chuck 120 is bonded to a base plate 110.

The base plate 110 is a circular member made of metal such as aluminum. The base plate 110 is a base member for fixing the electrostatic chuck 120. The base plate 110 is attached to a semiconductor manufacturing device, for example, and causes the substrate fixing device 100 to function as a semiconductor holding device that holds a wafer. Note that, the base plate 110 may also be attached to, for example, an exposure device, a machining device, a bonding device, a measuring device, an inspection device, or the like, in addition to the semiconductor manufacturing device, and may cause the substrate fixing device 100 to function as a semiconductor holding device.

The electrostatic chuck 120 is bonded to the base plate 110 and is configured to adsorb a target object such as a wafer by using an electrostatic force. The electrostatic chuck 120 is a circular member having a smaller diameter than the base plate 110, and one surface thereof is bonded to a center of the base plate 110. The electrostatic chuck 120 is configured to adsorb the target object such as a wafer on an adsorption surface on an opposite side to a bonding surface bonded to the base plate 110. That is, the electrostatic chuck 120 is made of a ceramic having an adsorption electrode built-in (near the adsorption surface) below the adsorption surface, and is configured to adsorb the target object on the adsorption surface by the electrostatic force when a voltage is applied from the base plate 110 to the adsorption electrode.

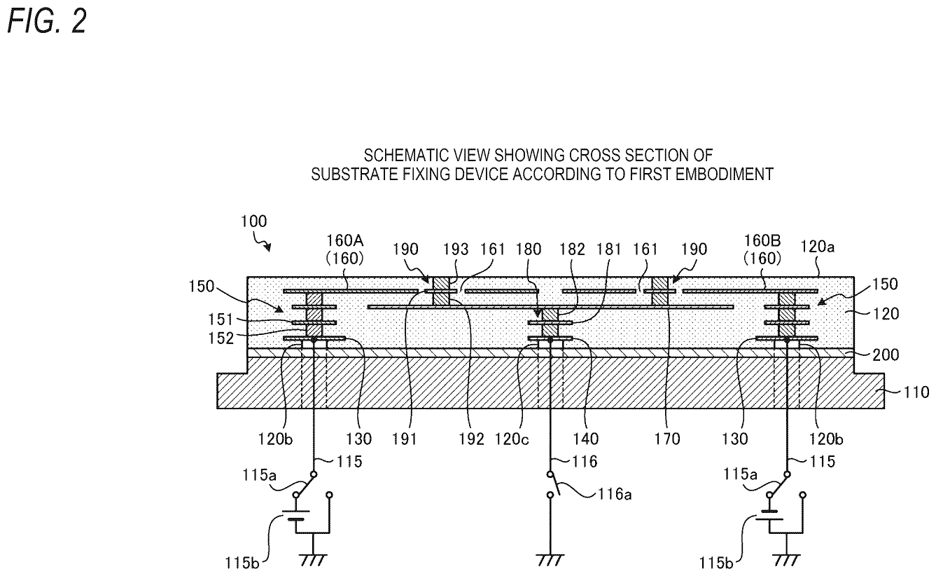

FIG. 2 is a schematic view showing a cross section of the substrate fixing device 100 according to the first embodiment. FIG. 2 schematically shows a cross section taken along a line II-II in FIG. 1. As shown in FIG. 2, the substrate fixing device 100 is constituted by bonding the electrostatic chuck 120 to the base plate 110 via an adhesive layer 200. Hereinafter, for convenience, a direction from the base plate 110 toward the electrostatic chuck 120 is described as an upward direction, and a direction from the electrostatic chuck 120 toward the base plate 110 is described as a downward direction. However, the substrate fixing device 100 may be manufactured and used in any posture such as an upside down posture.

The base plate 110 is a member made of a metal such as aluminum and having a thickness of 5 mm to 100 mm. The base plate 110 is provided with a power supply line 115 to penetrate through the same. The power supply line 115 is formed, for example, in a pin shape, penetrates the adhesive layer 200, and is connected to a power supply pad 130 of the electrostatic chuck 120. The power supply line 115 is in contact with the power supply pad 130, so that power is supplied to a wiring 150 in the electrostatic chuck 120. A switch 115a is connected to the power supply line 115. The switch 115a can switch connection between the power supply line 115 and an anode or a cathode of a DC power supply 115b and the connection between the power supply line 115 and a ground potential.

The base plate 110 is provided with a ground line 116 to penetrate through the same. The ground line 116 is switched between a state of being connected to the ground potential and a state of not being connected to the ground potential by a switch 116a. The ground line 116 is formed, for example, in a pin shape, penetrates through the adhesive layer 200, and is connected to a ground pad 140 of the electrostatic chuck 120. A wiring 180 and the ground line 116 connected to a ground electrode 170 are connected to the ground potential, whereby the ground pad 140 is connected to the ground potential.

The electrostatic chuck 120 includes a built-in conductive wiring 150 and is made of, for example, a ceramic plate obtained by firing aluminum oxide. A thickness of the electrostatic chuck 120 is, for example, about 1 mm to 20 mm. A cavity 120b, which is a concave portion capable of accommodating the power supply line 115 of the base plate 110, is formed at an outer peripheral portion of a lower surface of the electrostatic chuck 120, and a lower surface of the power supply pad 130 is exposed to the cavity 120b. A tip end of the power supply line 115 is in contact with the lower surface of the power supply pad 130, so that power is supplied from the base plate 110 to the wiring 150 in the electrostatic chuck 120.

An upper surface of the electrostatic chuck 120 is an adsorption surface 120a that adsorbs the target object. An adsorption electrode 160 for generating an electrostatic force is built-in near and below the adsorption surface 120a. The power supply pad 130 in contact with the power supply line 115 is built-in near the lower surface of the electrostatic chuck 120 on an opposite side to the adsorption surface 120a. The power supply pad 130 and the adsorption electrode 160 are electrically connected to each other by the wiring 150 formed by laminating a plurality of connection pads 151 and vias 152. That is, That is, a plurality of layers of connection pads 151 are arranged between the power supply pad 130 in contact with the power supply line 115 and the adsorption electrode 160. The power supply pad 130 and the connection pad 151, the connection pads 151 provided adjacent to each other, and the connection pad 151 and the adsorption electrode 160 are connected by the vias 152, respectively.

In the configuration shown in FIG. 2, the adsorption electrode 160 is a bipolar electrode, and is separated into a first electrode 160A and a second electrode 160B. The first electrode 160A is a positive electrode connectable to the positive electrode of the DC power supply 115b, and the second electrode 160B is a negative electrode connectable to the negative electrode of the DC power supply 115b. The first electrode 160A and the second electrode 160B are each formed of a plurality of semicircular arc-shaped conductor patterns arranged concentrically, and are disposed inside the electrostatic chuck 120 such that chord sides of the semicircular arcs face each other. In each of the first electrode 160A and the second electrode 160B, a passing portion 161 for passing a ground wiring 190 to be described later is formed. The passing portion 161 may be, for example, a gap between conductor patterns in each of the first electrode 160A and the second electrode 160B. Further, the passing portion 161 may be, for example, a through hole penetrating the adsorption electrode 160 in a thickness direction.

The first electrode 160A and the second electrode 160B may each be formed of a semicircular conductor pattern, and may be disposed inside the electrostatic chuck 120 such that the chord sides of the semicircles face each other. In this case, the passing portion 161 may be, for example, a through hole penetrating the adsorption electrode 160 in the thickness direction.

Two sets of the wiring 150 are disposed on left and right sides according to the first electrode 160A and the second electrode 160B of the adsorption electrode 160, and each wiring 150 is formed by laminating two layers of connection pads 151 between the power supply pad 130 and the adsorption electrode 160.

The connection pad 151 is formed of a conductor such as tungsten or molybdenum. The via 152 is formed by filling a via hole formed between the connection pads 151 formed in the adjacent layers with a conductor such as tungsten or molybdenum.

The ground electrode 170 is disposed between the lower surface of the electrostatic chuck 120 and the adsorption electrode 160 in the electrostatic chuck 120. The ground electrode 170 is disposed, for example, at the same height position as the connection pad 151 closest to the adsorption electrode 160. The ground electrode 170 is made of a metal such as tungsten or molybdenum, has a circular pattern with a diameter of about 270 mm to 300 mm and a thickness of about 10 μm to 50 μm, and is connectable to the ground potential. Specifically, a cavity 120c, which is a concave portion capable of accommodating an end portion of the ground line 116 of the base plate 110, is formed in a central portion of the lower surface of the electrostatic chuck 120, and a lower surface of the ground pad 140 in contact with the ground line 116 is exposed to the cavity 120c. The ground pad 140 and the ground electrode 170 are connected by the wiring 180 formed by laminating a connection pad 181 and a via 182.

The end portion of the ground line 116 connected to the ground potential is connected to the lower surface of the ground pad 140, whereby the ground electrode 170 is connected to the ground potential. For example, when a target object is adsorbed to the adsorption surface 120a of the electrostatic chuck 120, the power supply line 115 is connected to the anode or the cathode of the DC power supply 115b by the switch 115a, and the ground line 116 is disconnected from the ground potential by the switch 116a. As a result, the ground electrode 170 is disconnected from the ground potential. On the other hand, when the target object is detached from the adsorption surface 120a, the power supply line 115 is connected to the ground potential by the switch 115a, and the ground line 116 is connected to the ground potential by the switch 116a. Thus, the ground electrode 170 is connected to the ground potential.

The ground electrode 170 is connected to the ground wiring 190 (an example of a wiring) formed by laminating a connection pad 191 and vias 192 and 193. The ground wiring 190 extends through the passing portion 161 of the adsorption electrode 160 to the adsorption surface 120a of the electrostatic chuck 120. The ground electrode 170 and the adsorption surface 120a are electrically connected to each other by the ground wiring 190 formed by laminating the connection pad 191 and the vias 192 and 193. That is, for example, one layer of the connection pad 191 is disposed between the ground electrode 170 and the adsorption surface 120a. The ground electrode 170 and the connection pad 191 are connected by the via 192 (an example of a first via), and the connection pad 191 and the adsorption surface 120a are connected by the via 193 (an example of a second via). An end surface of the via 193, that is, an end surface of the ground wiring 190 is exposed from the adsorption surface 120a.

As described above, the ground electrode 170 connectable to the ground potential is disposed in the electrostatic chuck 120, and the ground wiring 190 extending to the adsorption surface 120a is connected to the ground electrode 170. Therefore, when the application of the voltage to the adsorption electrode 160 is stopped, electric charges remaining on the adsorption surface 120a can be escaped to the ground electrode 170 via the ground wiring 190. That is, since an amount of the electric charges remaining on the adsorption surface 120a is reduced, it is possible to reduce generation of an adsorption force between the adsorption surface 120a and the wafer due to the charging of the adsorption surface 120a. As a result, it is possible to facilitate detachment of the wafer from the adsorption surface 120a.

In the configuration shown in FIG. 2, two sets of ground wirings 190 are disposed on the left and right sides according to the first electrode 160A and the second electrode 160B of the adsorption electrode 160. Each ground wiring 190 is formed by laminating one layer of the connection pad 191 and the vias 192 and 193 between the ground electrode 170 and the adsorption surface 120a.

The connection pad 191 is formed of a conductor such as tungsten or molybdenum. The via 192 is formed by filling a via hole formed between the ground electrode 170 and the connection pad 191 with a conductor such as tungsten or molybdenum. The via 193 is formed by filling a via hole formed between the connection pad 191 and the adsorption surface 120a with a conductor such as tungsten or molybdenum.

The connection pad 191 is disposed at the same height position as the adsorption electrode 160 in the thickness direction of the electrostatic chuck 120. That is, the connection pad 191 is disposed in the passing portion 161 of the adsorption electrode 160 electrically independent of the adsorption electrode 160, and is disposed in the same layer as the adsorption electrode 160 in a side view. A lower surface of the connection pad 191 is connected to the upper surface of the adsorption electrode 160 by the via 192. The lower surface of the connection pad 191 has a larger area than an end surface of the via 192 in contact with the connection pad 191. An upper surface of the connection pad 191 is connected to the adsorption surface 120a of the electrostatic chuck 120 by the via 193. The upper surface of the connection pad 191 has a larger area than an end surface of the via 193 in contact with the connection pad 191.

As described above, in the embodiment, the connection pad 191 of the ground wiring 190 is disposed at the same height position as the adsorption electrode 160, the connection pad 191 and the ground electrode 170 are connected by the via 192, and the connection pad 191 and the adsorption surface 120a are connected by the via 193. That is, in the passing portion 161 of the ground wiring 190 in the adsorption electrode 160, the via 192 and the via 193 are not directly connected to each other but are connected to each other via the connection pad 191. Therefore, even when a positional deviation of the vias 192 and 193 in a horizontal direction occurs at the passing portion 161 of the adsorption electrode 160 due to difference in an amount of thermal shrinkage between the green sheets constituting the electrostatic chuck 120 (the ceramic plate), it is possible to prevent the connection between the via 192 and the via 193 from being hindered. As a result, connection reliability of the ground wiring 190 can be improved.

The via 193 has an end surface exposed from the adsorption surface 120a of the electrostatic chuck 120. The exposed end surface of the via 193 may be located on the same plane as the adsorption surface 120a. The exposed end surface of the via 193 may be located at a position lower than the adsorption surface 120a. Since the end surface of the via 193 is exposed from the adsorption surface 120a, the electric charges accumulated on the adsorption surface 120a can be quickly escaped to the ground electrode 170, so that it is possible to facilitate detachment of the wafer from the adsorption surface 120a.

The connection pad 191 is disposed in the passing portion 161 of the adsorption electrode 160 electrically independent of the adsorption electrode 160. As a result, it is possible to prevent a decrease in electrostatic force caused by electric leakage from the adsorption electrode 160 to the connection pad 191.

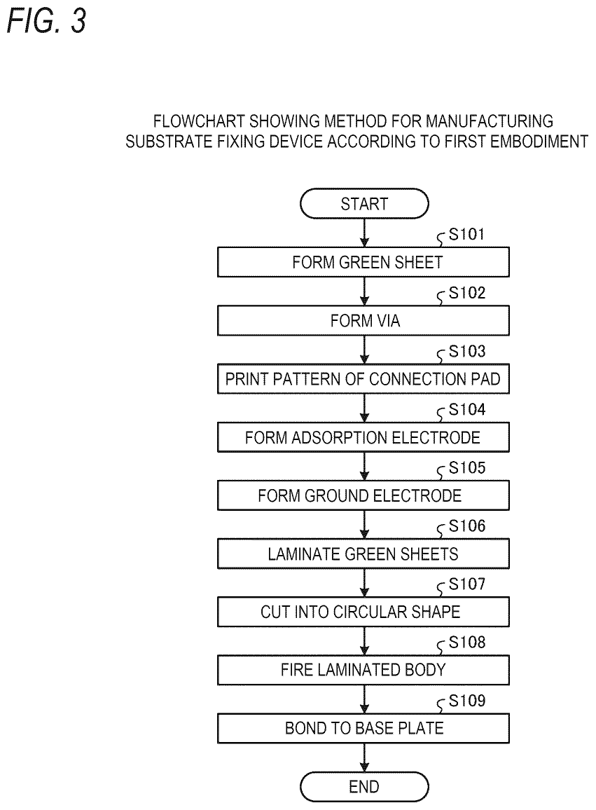

Next, a method for manufacturing the substrate fixing device 100 according to the first embodiment will be described with reference to FIG. 3. FIG. 3 is a flowchart showing the method for manufacturing the substrate fixing device 100 according to the first embodiment.

First, in order to form the electrostatic chuck 120, a plurality of green sheets are manufactured (step S101). Specifically, a green sheet is produced by drying a slurry-like mixture obtained by mixing, for example, aluminum oxide and a predetermined auxiliary agent. The green sheet is, for example, a square sheet with a length and width of 500 mm×500 mm having a thickness of 0.7 mm.

In each green sheet, the via 152 for connecting the connection pad 151 formed in the adjacent layers and the via 182 for connecting the connection pad 181 formed in the adjacent layers are formed. In addition, the via 192 for connecting the ground electrode 170 and the connection pad 191 or the via 193 for connecting the adsorption surface 120a and the connection pad 191 is appropriately formed in each green sheet (step S102). Specifically, via holes penetrating the green sheet are formed at positions where the connection pads 151 formed in the adjacent layers overlap each other and at positions where the connection pads 181 formed in the adjacent layers overlap each other, and the via holes are filled with a conductor such as tungsten or molybdenum, thereby forming the vias 152 and 182. In addition, a via hole penetrating the green sheet is formed at a position where the ground electrode 170 and the connection pad 191 overlap each other, and the via hole is filled with a conductor such as tungsten or molybdenum, thereby forming the via 192. Further, a via hole penetrating the green sheet is formed at a position where the adsorption surface 120a and the connection pad 191 overlap each other, and the via hole is filled with a conductor such as tungsten or molybdenum, thereby forming the via 193.

Similarly to the via holes, the cavities 120b and 120c are formed as through holes penetrating the green sheet. That is, the through holes of the plurality of laminated green sheets are connected to form openings, so that the cavities 120b and 120c are formed.

Patterns of the connection pads 151 and 181 are printed on the green sheet on which the vias 152 and 182 are formed, and a pattern of the connection pad 191 is printed on the green sheet on which the via 192 is formed (step S103). That is, the connection pads 151, 181, and 191 are formed by printing a metal paste such as tungsten or molybdenum on the surface of the green sheets.

The adsorption electrode 160 is formed on the green sheet on which the connection pad 191 is formed and which is laminated near the adsorption surface 120a of the electrostatic chuck 120 (step S104). At this time, the passing portion 161 through which the ground wiring 190 passes is formed in the adsorption electrode 160, and the connection pad 191 is accommodated in the passing portion 161. Accordingly, the connection pad 191 is disposed in the same layer as the adsorption electrode 160.

Further, the ground electrode 170 is formed on the green sheet laminated between the lower surface of the electrostatic chuck 120 on the opposite side to the adsorption surface 120a and the adsorption electrode 160 (step S105).

The green sheets on which the connection pads 151, 181, and 191, the adsorption electrode 160, and the ground electrode 170 are formed in this manner are laminated on each other (step S106). That is, the green sheets are laminated in such an order that the connection pads 151 and 181, the adsorption electrode 160, and the ground electrode 170 formed in the layers of the adjacent green sheets are connected by the vias 152 and 182, and the connection pad 191, the ground electrode 170, and the adsorption surface 120a are connected by the vias 192 and 193. As a result, the plurality of connection pads 151 and the vias 152 are laminated to form the wiring 150, and the connection pad 181 and the via 182 are laminated to form the wiring 180. The connection pad 191 and the vias 192 and 193 are laminated to form the ground wiring 190. On the adsorption surface 120a, the end surface of the via 193, that is, the end surface of the ground wiring 190 is exposed. Then, a laminated body of the green sheets is cut into a circular shape in accordance with a shape of the base plate 110 (step S107).

The laminated body cut into a circular shape is fired to become a ceramic in a firing furnace (step S108). The laminated body is thermally shrunk by firing. At this time, the positional deviation of the vias 192 and 193 occurs in the horizontal direction at the passing portion 161 of the adsorption electrode 160 due to a difference in the amount of thermal shrinkage between the green sheets constituting the laminated body. However, since the via 192 and the via 193 are connected via the connection pad 191, it is possible to prevent the connection between the via 192 and the via 193 from being hindered. As a result, the connection reliability of the ground wiring 190 can be improved even during firing in which the laminated body is exposed to a high temperature.

A thickness of the ceramic circular plate obtained by firing is, for example, about 10 mm. Since the laminated body is thermally shrunk by firing, the thickness of the circular plate is smaller than the thickness of the laminated body before firing. The ceramic circular plate thus formed becomes the electrostatic chuck 120, and the electrostatic chuck 120 is bonded to the metal base plate 110 by the adhesive layer 200 (step S109). For example, a bonding material is used to form the adhesive layer 200. Accordingly, the substrate fixing device 100 is completed.

As described above, the electrostatic chuck (for example, the electrostatic chuck 120) according to the first embodiment includes a ceramic plate, the adsorption electrode (for example, the adsorption electrode 160), a ground electrode (for example, the ground electrode 170), and a wiring (for example, the ground wiring 190). The adsorption electrode is built-in below and near one surface (for example, the adsorption surface 120a) of the ceramic plate. The ground electrode is disposed between the other surface of the ceramic plate and the adsorption electrode in the ceramic plate and is connectable to a ground potential. The wiring is connected to the ground electrode in the ceramic plate, and extends through the adsorption electrode to the one surface of the ceramic plate. The wiring includes a connection pad (for example, the connection pad 191) disposed at the same height position as the adsorption electrode, a first via (for example, the via 192) connecting the connection pad and the ground electrode, and a second via (for example, the via 193) connecting the connection pad and the one surface of the ceramic plate. Accordingly, the connection reliability of the wiring passing through the adsorption electrode can be improved.

The via 193 may have an end surface exposed from the one surface of the ceramic plate. Accordingly, it is possible to further facilitate the detachment of the wafer from the adsorption surface.

Further, the adsorption electrode may have a passing portion (for example, the passing portion 161) through which the wiring passes. The connection pad may be disposed in the passing portion electrically independent of the adsorption electrode. Accordingly, it is possible to prevent a decrease in electrostatic force caused by electric leakage from the adsorption electrode to the connection pad.

The arrangement of the ground electrode 170 and the structure of the ground wiring 190 described in the first embodiment can be variously changed. Hereinafter, a modification of the substrate fixing device 100 will be specifically described.

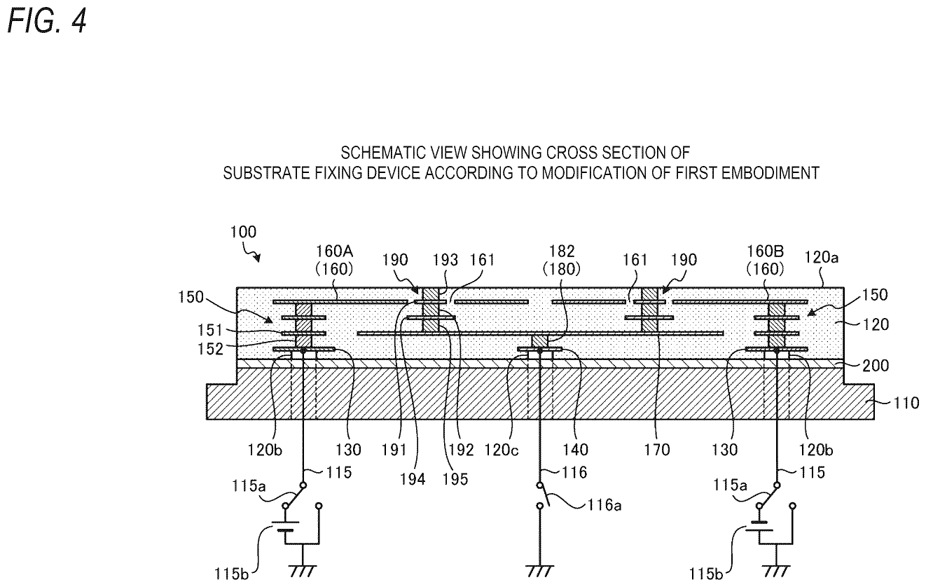

FIG. 4 is a schematic view showing a cross section of the substrate fixing device 100 according to the modification of the first embodiment. In FIG. 4, the same portions as those in FIG. 2 are denoted by the same reference numerals.

As shown in FIG. 4, in the substrate fixing device 100 according to the modification, the ground electrode 170 is disposed at the same height position as the connection pad 151 farthest from the adsorption electrode 160. The ground electrode 170 and the ground pad 140 are connected by a wiring 180 including only a via 182.

The ground electrode 170 and the adsorption surface 120a are electrically connected to each other by the ground wiring 190 formed by laminating the connection pads 191 and 194 and the vias 192, 193, and 195. That is, for example, the connection pads 191 and 194 formed in two layers adjacent to each other are disposed between the ground electrode 170 and the adsorption surface 120a. The connection pad 194 (an example of another connection pad) is disposed closer to the ground electrode 170 than the connection pad 191. The ground electrode 170 and the connection pad 194 are connected by the via 195, the connection pads 191 and 194 formed in two adjacent layers are connected by the via 192 (an example of the first via), and the connection pad 191 and the adsorption surface 120a are connected by the via 193 (an example of the second via). The end surface of the via 193, that is, the end surface of the ground wiring 190 is exposed from the adsorption surface 120a.

As described above, in the substrate fixing device 100 according to the modification, the via 192 of the ground electrode 170 connects the connection pad 191 disposed in the passing portion 161 of the adsorption electrode 160 and the connection pad 194 disposed closer to the ground electrode 170 than the connection pad 191. Even in this case, since the via 192 and the via 193 are connected to each other via the connection pad 191 in the passing portion 161 of the adsorption electrode 160, it is possible to prevent the connection between the via 192 and the via 193 from being hindered, and to improve the connection reliability of the ground wiring 190.

The connection pad 191 may be smaller in size than the connection pad 194 in a direction (horizontal direction) perpendicular to an extending direction of the ground wiring 190. Accordingly, the size of the passing portion 161 in the adsorption electrode 160 can be reduced, and as a result, a decrease in the electrostatic force caused by a decrease in a volume of the adsorption electrode 160 can be prevented.

### Second Embodiment

A second embodiment relates to a variation of the structure of the adsorption surface 120a of the electrostatic chuck 120 in the first embodiment.

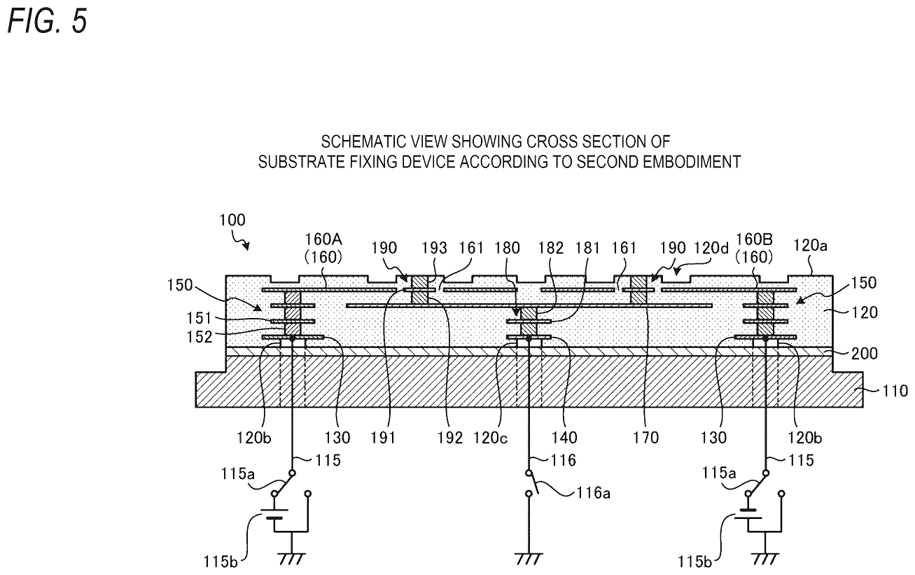

FIG. 5 is a schematic view showing a cross section of the substrate fixing device 100 according to the second embodiment. In FIG. 5, the same portions as those in FIG. 2 are denoted by the same reference numerals.

As shown in FIG. 5, in the second embodiment, a concave portion 120d may be formed in the adsorption surface 120a of the electrostatic chuck 120. The concave portion 120d is formed to surround a predetermined region including the end surface of the via 193 exposed from the adsorption surface 120a. The concave portion 120d is formed by, for example, blasting the adsorption surface 120a in a state where a mask is formed in a predetermined region including the end surface of the via 193 exposed from the adsorption surface 120a. A depth of the concave portion 120d may be, for example, about 10 μm.

As described above, since the concave portion 120d surrounding the predetermined region including the exposed end surface of the via 193 is formed on the adsorption surface 120a of the electrostatic chuck 120, a contact area between the adsorption surface 120a and the wafer can be reduced, and damage of the wafer can be prevented.

### Third Embodiment

A third embodiment is different from the second embodiment in that an insulating film is formed on the adsorption surface 120a of the electrostatic chuck 120.

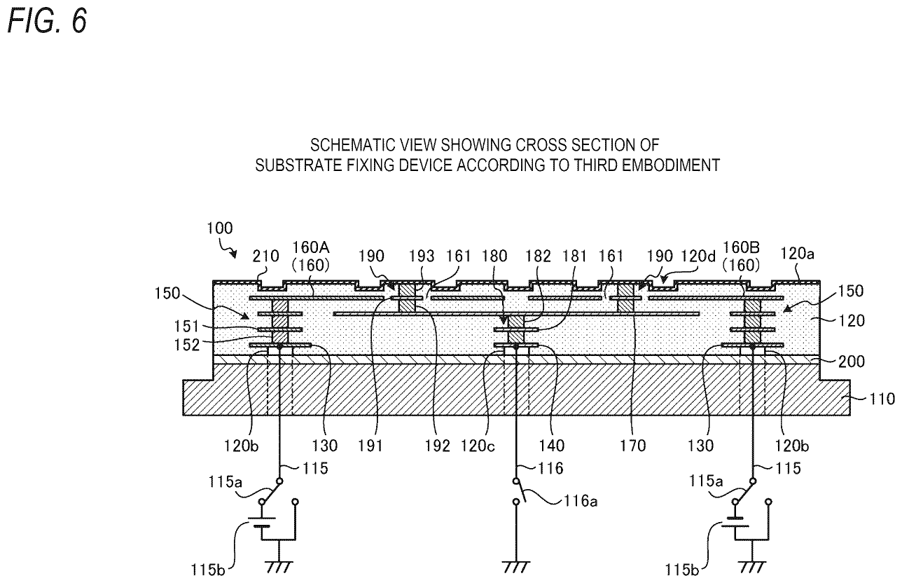

FIG. 6 is a schematic view showing a cross section of the substrate fixing device 100 according to the third embodiment. In FIG. 6, the same portions as those in FIG. 5 are denoted by the same reference numerals.

As shown in FIG. 6, in the third embodiment, an insulating film 210 may be formed on the adsorption surface 120a of the electrostatic chuck 120. The insulating film 210 covers the adsorption surface 120a of the electrostatic chuck 120 and the end surface of the via 193 exposed from the adsorption surface 120a. When the concave portion 120d is formed in the adsorption surface 120a, the insulating film 210 also covers an inner surface of the concave portion 120d. The insulating film 210 is formed by thermal spraying, vapor deposition, sputtering, or chemical vapor deposition (CVD) using, for example, aluminum oxide, yttrium oxide, a silicon oxide film (SiO2), a silicon nitride film (SiN), diamond-like carbon or the like as a material. A thickness of the insulating film 210 may be, for example, about 0.1 μm to 1 μm.

As described above, since the adsorption surface 120a of the electrostatic chuck 120 and the end surface of the via 193 exposed from the adsorption surface 120a are covered with the insulating film 210, it is possible to prevent generation of particles due to contact between the via 193 and the wafer.

### Fourth Embodiment

A fourth embodiment is different from the third embodiment in a covering range of the insulating film 210.

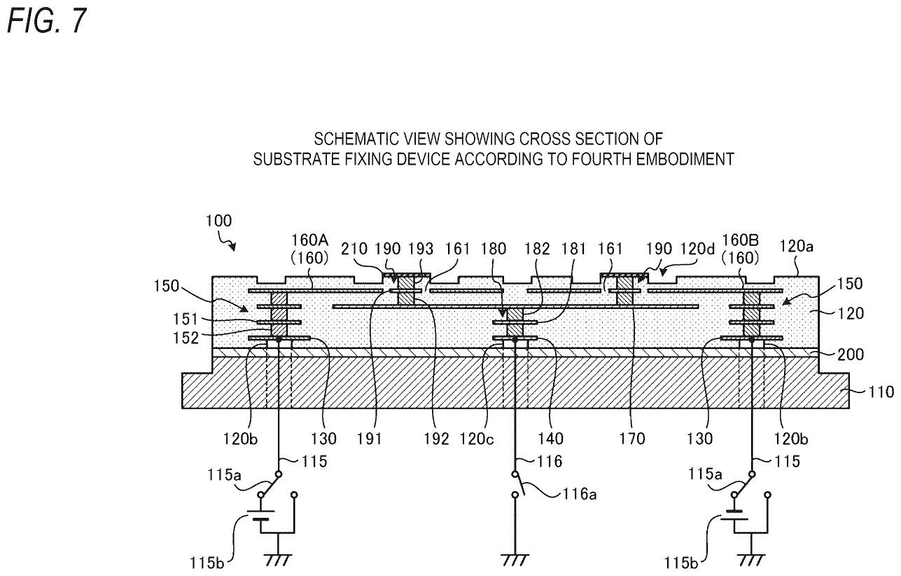

FIG. 7 is a schematic view showing a cross section of the substrate fixing device 100 according to the fourth embodiment. In FIG. 7, the same portions as those in FIG. 6 are denoted by the same reference numerals.

As shown in FIG. 7, in the fourth embodiment, the insulating film 210 covers only the end surface of the via 193 exposed from the adsorption surface 120a and the adsorption surface 120a around the end surface. Thus, as compared with the third embodiment, the covering range of the insulating film 210 can be reduced, so that an amount of the material used for the insulating film 210 can be reduced.

### Fifth Embodiment

A fifth embodiment is different from the first embodiment in the structure of the via 193 in the ground wiring 190.

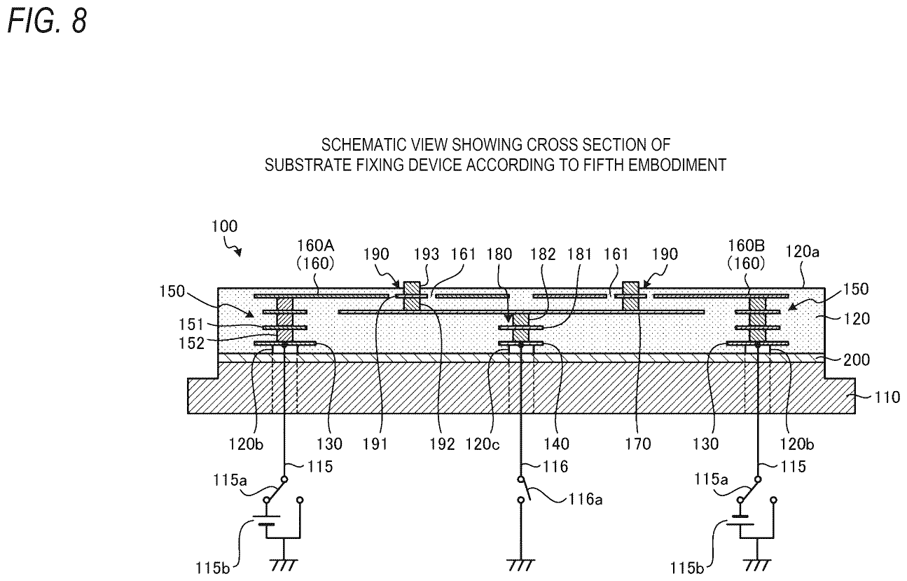

FIG. 8 is a schematic view showing a cross section of the substrate fixing device 100 according to the fifth embodiment. In FIG. 8, the same portions as those in FIG. 2 are denoted by the same reference numerals.

As shown in FIG. 8, in the fifth embodiment, an end portion of the via 193 may protrude from the adsorption surface 120a. Therefore, the via 193 is in contact with the wafer adsorbed to the adsorption surface 120a. Accordingly, since the electric charges accumulated in the wafer in addition to the adsorption surface 120a can be quickly escaped to the ground electrode 170, it is possible to further facilitate the detachment of the wafer from the adsorption surface 120a.

The end portion of the via 193 protruding from the adsorption surface 120a is formed by blasting a region of the adsorption surface 120a that does not overlap the via 193.

### Sixth Embodiment

A sixth embodiment is different from the fifth embodiment in that an insulating film is formed on the adsorption surface 120a of the electrostatic chuck 120.

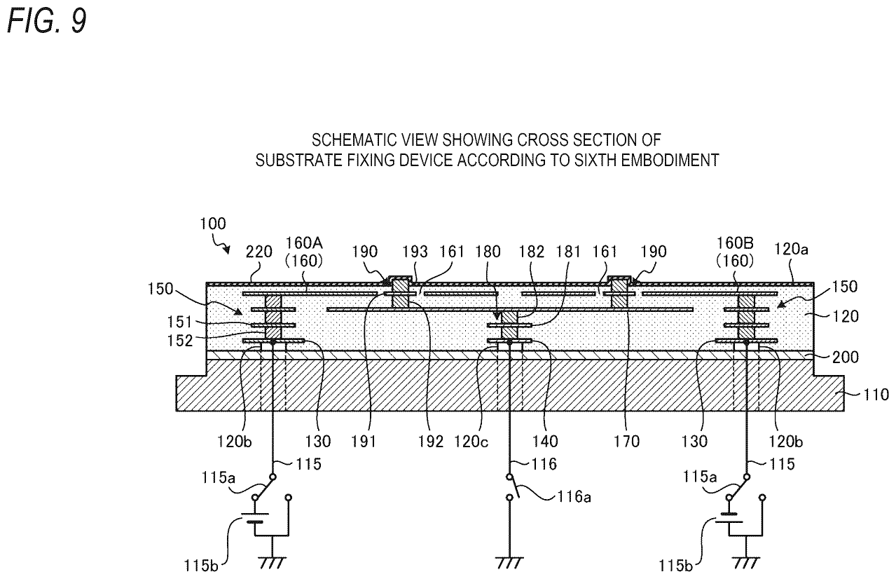

FIG. 9 is a schematic view showing a cross section of the substrate fixing device 100 according to the sixth embodiment. In FIG. 9, the same portions as those in FIG. 8 are denoted by the same reference numerals.

As shown in FIG. 9, in the sixth embodiment, an insulating film 220 may be formed on the adsorption surface 120a of the electrostatic chuck 120. The insulating film 220 covers the adsorption surface 120a of the electrostatic chuck 120 and the end portion of the via 193 protruding from the adsorption surface 120a. The insulating film 220 is formed by thermal spraying, vapor deposition, sputtering, or CVD using, for example, aluminum oxide, yttrium oxide, a silicon oxide film (SiO2), a silicon nitride film (SiN), diamond-like carbon or the like as a material. A thickness of the insulating film 220 may be, for example, about 0.1 μm to 1 μm.

As described above, since the adsorption surface 120a of the electrostatic chuck 120 and the end portion of the via 193 protruding from the adsorption surface 120a are covered with the insulating film 220, it is possible to prevent the generation of particles due to contact between the via 193 and the wafer.

### Seventh Embodiment

A seventh embodiment is different from the sixth embodiment in a covering range of the insulating film 220.

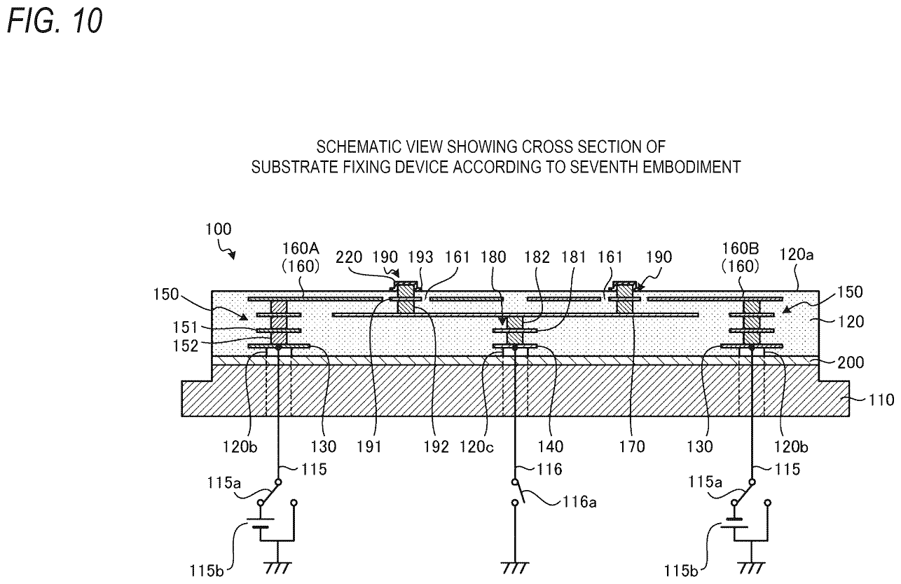

FIG. 10 is a schematic view showing a cross section of the substrate fixing device 100 according to the seventh embodiment. In FIG. 10, the same portions as those in FIG. 9 are denoted by the same reference numerals.

As shown in FIG. 10, in the seventh embodiment, the insulating film 220 covers only the end surface of the via 193 protruding from the adsorption surface 120a and the adsorption surface 120a around the end portion. Thus, as compared with the sixth embodiment, the covering range of the insulating film 220 can be reduced, so that the amount of the material used for the insulating film 220 can be reduced.

### Other Embodiments

In each of the above embodiments, the adsorption electrode 160 is a bipolar electrode, but the adsorption electrode 160 may be a unipolar electrode. For example, the adsorption electrode 160 may be formed of one non-separated circular plate-shaped conductor pattern. In this case, one set of the power supply pad 130 and the wiring 150 is arranged for the adsorption electrode 160.

Even when the adsorption electrode 160 is a unipolar electrode, since the ground electrode 170 is disposed in the electrostatic chuck 120 and the ground wiring 190 is connected to the ground electrode 170, the electric charges on the adsorption surface 120a can be escaped to the ground electrode 170 via the ground wiring 190.

What is claimed is:

1. An electrostatic chuck comprising:
a ceramic plate;
an adsorption electrode built-in below one surface of the ceramic plate;
a ground electrode disposed between another surface of the ceramic plate and the adsorption electrode in the ceramic plate and connectable to a ground potential; and
a wiring connected to the ground electrode in the ceramic plate and extending through the adsorption electrode to the one surface of the ceramic plate, wherein
the wiring includes
a connection pad disposed at a same height position as the adsorption electrode,
a first via connecting the connection pad and the ground electrode or another connection pad disposed closer to the ground electrode than the connection pad, and
a second via connecting the connection pad and the one surface of the ceramic plate.

2. The electrostatic chuck according to claim 1, wherein
the second via has an end surface exposed from the one surface of the ceramic plate.

3. The electrostatic chuck according to claim 2, wherein
the one surface of the ceramic plate has a concave portion surrounding a predetermined region including the exposed end surface of the second via.

4. The electrostatic chuck according to claim 2, further comprising:
an insulating film covering the one surface of the ceramic plate and the exposed end surface of the second via.

5. The electrostatic chuck according to claim 1, wherein
the second via has an end portion protruding from the one surface of the ceramic plate.

6. The electrostatic chuck according to claim 5, further comprising:
an insulating film covering the one surface of the ceramic plate and the protruding end portion of the second via.

7. The electrostatic chuck according to claim 1, wherein
the adsorption electrode has a passing portion through which the wiring passes, and
the connection pad is disposed in the passing portion electrically independently of the adsorption electrode.

8. The electrostatic chuck according to claim 7, wherein
the first via connects the connection pad disposed in the passing portion and the other connection pad, and
the connection pad is smaller in size than the other connection pad in a direction perpendicular to an extending direction of the wiring.

9. A substrate fixing device comprising:
a base plate; and
an electrostatic chuck fixed to the base plate and configured to adsorb a substrate by an electrostatic force, wherein
the electrostatic chuck includes
a ceramic plate,
an adsorption electrode built-in below one surface of the ceramic plate,
a ground electrode disposed between another surface of the ceramic plate and the adsorption electrode in the ceramic plate and connectable to a ground potential, and
a wiring connected to the ground electrode in the ceramic plate and extending through the adsorption electrode to the one surface of the ceramic plate, and
the wiring includes
a connection pad disposed at a same height position as the adsorption electrode,
a first via connecting the connection pad and the ground electrode or another connection pad disposed closer to the ground electrode than the connection pad, and
a second via connecting the connection pad and the one surface of the ceramic plate.
